(19) United States
(12) Patent Application Publication
(10) Pub. No.: US 2024/0427959 A1
(43) Pub. Date: Dec. 26, 2024

(54) SIMULATION DEVICE, SIMULATION METHOD, AND SIMULATION PROGRAM

(71) Applicant: NIPPON TELEGRAPH AND TELEPHONE CORPORATION, Tokyo (JP)

(72) Inventors: Muneyuki KAWATANI, Tokyo (JP); Kenji KOMIYA, Tokyo (JP); Atsushi ISOMURA, Tokyo (JP); Masaru TAKAGI, Tokyo (JP)

(73) Assignee: NIPPON TELEGRAPH AND TELEPHONE CORPORATION, Tokyo (JP)

(21) Appl. No.: 18/698,744

(22) PCT Filed: Oct. 6, 2021
(86) PCT No.: PCT/JP2021/037071

§ 371 Date: Apr. 4, 2024

(51) Int. Cl. G06F 30/20

(52) U.S. Cl. CPC G06F 30/20

(57) ABSTRACT

An acquisition unit (15a) acquires real data. A calculation unit (15b) performs a simulation using a predetermined parameter and calculates a simulation result. A selection unit (15c) compares the simulation result with the real data corresponding to the simulation result, and selects a parameter such that the simulation result is assimilated with the real data, and the calculation unit (15b) performs the simulation using the selected parameter as the predetermined parameter.

### TECHNICAL FIELD

The present invention relates to a simulation device, a simulation method, and a simulation program.

### BACKGROUND ART

In recent years, technology called a digital twin in which an environment of a real space is reproduced in a digital virtual space to perform analysis and prediction has been anticipated. In addition, a technique for performing a simulation using a prediction model for constructing a digital twin in an urban society is known (refer to NPL 1).

### CITATION LIST

### Non Patent Literature

[NPL 1] S.M. Sohel Mahmud, Luis Ferreira, Md. Shamsul Hoque, Ahmad Tavassoli, “Micro-simulation modelling for traffic safety: A review and potential application to heterogeneous traffic environment”, IATSS Research 43 (2019), 2019, pp. 27-36

### SUMMARY OF INVENTION

### Technical Problem

According to the related art, it was difficult to perform a large-scale simulation of traffic or the like using a prediction model with high accuracy. For example, in a traffic simulation prediction model, there were a huge number of parameters such as shapes and speed limits of roads, positions of intersections and traffic regulations, the presence or absence and indication patterns of traffic lights, the appearance times and destinations of vehicles, and the presence or absence of parking on roads, and the search process for determining the optimum parameters took an enormous amount of time.

The present invention has been made in view of the above, and an object of the present invention is to efficiently determine a parameter optimal for a large-scale simulation using a prediction model, and to perform a highly accurate simulation.

### Solution to Problem

In order to solve the above-mentioned problem and achieve the object, a simulation device according to the present invention includes: an acquisition unit configured to acquire real data; a calculation unit configured to perform a simulation using a predetermined parameter and calculate a simulation result; and a selection unit configured to compare the simulation result with the real data corresponding to the simulation result, and select a parameter such that the simulation result and the real data are assimilated, and the calculation unit performs the simulation using the selected parameter as the predetermined parameter.

### Advantageous Effects of Invention

According to the present invention, it is possible to efficiently determine a parameter optimal for a large-scale simulation using a prediction model, and to perform a highly accurate simulation.

### BRIEF DESCRIPTION OF DRAWINGS

FIG. 1 is a schematic diagram illustrating a schematic configuration of a simulation device according to the present embodiment.

FIG. 2 is a diagram for describing processing of a selection unit.

FIG. 3 is a flowchart illustrating a simulation processing procedure.

FIG. 4 is a diagram illustrating an example of a computer that executes a simulation program.

### DESCRIPTION OF EMBODIMENTS

An embodiment of the present invention will be described in detail below with reference to the drawings. The present invention is not limited to the present embodiment. Further, in the description of the drawings, the same parts are denoted by the same reference signs.

### Configuration of Simulation Device

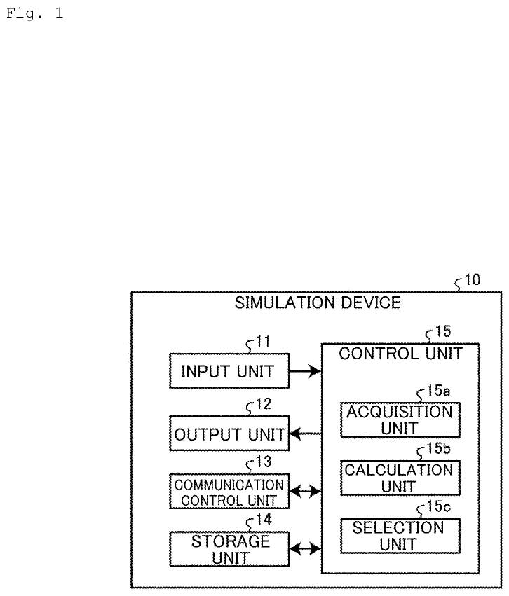

FIG. 1 is a schematic diagram illustrating a schematic configuration of a simulation device according to the present embodiment. As illustrated in FIG. 1, a simulation device 10 according to the present embodiment is implemented as a general-purpose computer such as a personal computer and includes an input unit 11, an output unit 12, a communication control unit 13, a storage unit 14, and a control unit 15.

The input unit 11 is implemented by using an input device such as a keyboard or a mouse and inputs various types of instruction information such as to start processing to the control unit 15 in response to an input operation from an operator. The output unit 12 is implemented by a display device such as a liquid crystal display, a printer, or the like. For example, the output unit 12 displays results of simulation processing, which will be described later.

The communication control unit 13 is implemented by a network interface card (NIC) or the like and controls communication between an external device and the control unit 15 via a telecommunication line such as a local area network (LAN) or the Internet. For example, the communication control unit 13 controls communication between the control unit 15 and a management device or the like that manages real data used for simulation processing, which will be described later.

The storage unit 14 is implemented by a semiconductor memory element such as a random access memory (RAM) or a flash memory, or a storage device such as a hard disk or an optical disc. The storage unit 14 stores in advance a processing program for operating the simulation device 10, data used during execution of the processing program, and the like, or temporarily performs storing each time the processing is performed. The storage unit 14 also stores map data, prediction models used for simulation processing, which will be described later, and the like. Note that the storage unit 14 may also be configured to communicate with the control unit 15 via the communication control unit 13.

The control unit 15 is implemented by using a central processing unit (CPU) or the like and executes a processing program stored in a memory. Accordingly, the control unit 15 functions as an acquisition unit 15a, a calculation unit 15b, and a selection unit 15c, as illustrated in FIG. 1.

Note that each or some of these functional units may be implemented in different hardware. For example, the acquisition unit 15a may be implemented in a device different from other functional units. Further, the control unit 15 may include another functional unit.

The acquisition unit 15a acquires real data. Specifically, the acquisition unit 15a acquires data such as actual statistical information to be compared with a simulation result in simulation processing to be described later. For example, in a case where a simulation related to traffic is performed, the real data is traffic condition data such as GPS position information, average vehicle speed and number of passing vehicles at a fixed point from a traffic counter or ETC, and camera images.

The acquisition unit 15a acquires this information via the input unit 11 or from a management device or the like that manages real data via the communication control unit 13. The acquisition unit 15a may cause the storage unit 14 to store the acquired real data.

The calculation unit 15b performs a simulation using a predetermined parameter and calculates a simulation result. Specifically, in the first iteration of simulation processing, which will be described later, a simulation is performed using a predetermined default value as a parameter. For example, in a case where the calculation unit 15b performs a simulation related to traffic, an average pattern is used as a default value of the indication of the traffic light.

Further, from the second iteration onwards, a simulation is performed using a parameter selected by the selection unit 15c, which will be described later.

The calculation unit 15b outputs, for example, position information of each vehicle at each time, that is, a trajectory as a simulation result related to traffic.

The selection unit 15c compares the simulation result with the real data corresponding to the simulation result, and selects a parameter such that the simulation result and the real data are assimilated. The selection unit 15c outputs the selected parameter to the calculation unit 15b as a predetermined parameter.

Specifically, the selection unit 15c first compares the simulation result with real data such as statistical data, and selects a parameter to perform a simulation close to the real data. For example, the selection unit 15c compares the statistic calculated from the simulation result with the statistic of real data to perform parameter correction for data assimilation.

Here, data assimilation involves comparing a simulation result with real data to modify the trajectory of the simulation to improve the certainty, that is, accuracy. Specifically, assimilation is a correction process in which the values and weights of a static map, a dynamic map, reliability accuracy of a map, a movement demand, properties of a vehicle, and the like are changed so that the observation result of the real world and the simulation result match each other even when the geographical space and the time information are changed.

Here, the static map is information such as the connection relationship between roads, the number of lanes, speed limits, one-way streets, directions in which there is no access at intersections, indication patterns of traffic lights, and the like that are described on commercially available maps. Also, the dynamic map is temporary road attribute information that is not described on a map, such as parking on roads, falling objects, road construction, and traffic regulations such as road closures due to stormy weather.

The reliability accuracy of a map is the degree of deterioration/improvement of the reliability of the map as a whole based on the time elapsed from the creation or editing date and time and the creation process. It also includes the degree of deterioration/improvement in the reliability of a part of information described on a map or a localized portion, such as the opening of new roads and the establishment of right-turn lanes, based on information such as the vehicle's GPS travel trajectory.

The movement demand is information about vehicles to be driven in the simulation, such as from which point to which point, on what route, how many vehicles will depart, and at what time. The properties of a vehicle are the so-called temperament of a driver, such as maximum acceleration, maximum deceleration, and how to keep a distance between vehicles. For example, they are used in a case where the number of inexperienced drivers increases during consecutive holidays and the number of cautious drivers increases during snowfall.

In the present embodiment, the data assimilation involves quantifying the occurrence place, time, and degree (range of influence) of traffic congestion using indicators such as average vehicle speed and traffic volume, searching for parameters that cause deviation, and adjusting these parameters.

Specifically, the selection unit 15c calculates statistics such as average vehicle speed in a certain time period in a certain section from position information at each time of each vehicle which is a simulation result related to traffic, and obtains traffic conditions such as congestion and traffic jam.

The selection unit 15c compares real time information about a cross-sectional traffic volume acquired from a traffic counter or the like by the acquisition unit 15a and real data such as past statistical data as correct data with the statistics of the simulation results, and evaluates quantitative accuracy. For example, the selection unit 15c calculates accuracy using a root mean squared error (RMSE) between the simulation result and the real data.

Next, the selection unit 15c lists road sections where there is a deviation between the simulation result and the real data, and road sections and intersections that may affect the traffic conditions of the road sections, and estimates the degree of influence. For example, upstream and downstream sections of the route, adjacent intersections, and road sections connected through these are listed, and the degree of influence is set according to the road distance from the section. Accordingly, the number of possible parameters to be corrected can be greatly reduced.

The selection unit 15c selects a parameter to be corrected for a road section in which the degree of influence exceeds a certain value. The possible parameters include the number of vehicles attempting to pass through the section, the number of vehicles parked on the road in the section, and the like. In a case where the map information is uncertain, the speed limit, the presence or absence of the traffic light, the indication pattern of the traffic light, and the like may be parameters to be corrected.

The selection unit 15c selects a parameter on the basis of the relation between the possible parameter to be corrected and the influence on the traffic condition, which has been investigated in advance. Specifically, the selection unit 15c selects a parameter value that is expected to eliminate the deviation most effectively within a range where the parameter value does not become an unnatural parameter value on the basis of uncertainty of the parameter.

For example, in a case where the simulation result shows that the congestion is higher than the real data, the selection unit 15c selects parameters, that is, corrects the values to extend the indication time of the green light at the intersection to which the road section is connected, thereby alleviating congestion and bringing the simulation result closer to the real data.

Further, the correction target time may be selected in accordance with the distance from the road section to the correction target section in consideration of the propagation speed of traffic congestion. For example, in a case where a traffic congestion situation at 15:00 in a certain road section deviates from the actual situation, the traffic volume at 14:55 in a road section of 2 km ahead may be adjusted.

The selection unit 15c outputs the selected parameter to the calculation unit 15b. That is, the simulation device 10 performs iteration of repeating the processing of the acquisition unit 15a, the calculation unit 15b, and the selection unit 15c.

Thus, the calculation unit 15b can bring the simulation result closer to the actual traffic condition using the parameter fed back from the selection unit 15c. In this manner, the simulation device 10 can easily improve the accuracy of simulation.

The selection unit 15c may select a plurality of parameter sets. In this case, the calculation unit 15b may execute simulation using a plurality of parameter sets in parallel.

The selection unit 15c repeats a process of selecting the parameter and outputting the parameter to the calculation unit 15b until the simulation result shows accuracy equal to or higher than a predetermined threshold value. In this case, the selection unit 15c calculates accuracy using, for example, an RMSE between the simulation result and the real data.

Alternatively, the selection unit 15c may perform iteration of repeating the process of selecting the parameter and outputting the parameter to the calculation unit 15b until a predetermined number of times is reached.

Note that the selection unit 15c may present the simulation result and the real data to be compared. For example, the selection unit 15c may output a comparison result between the simulation result and the real data to other devices via the output unit 12 and the communication control unit 13 and present it to a user.

In this case, the selection unit 15c may present a parameter for assimilating the simulation result and the real data. For example, the selection unit 15c presents a user with a parameter for assimilating the simulation result and the real data and a value after the change of the parameter. At that time, the selection unit 15c may present a plurality of parameters. The selection unit 15c may receive an instruction of a user who selects any of the plurality of presented parameters.

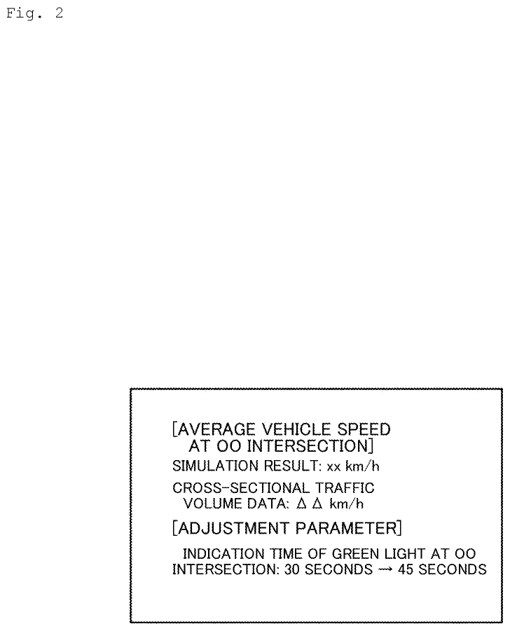

Here, FIG. 2 is a diagram for describing processing of the selection unit. FIG. 2 illustrates a screen presented to the user. In the example illustrated in FIG. 2, a traffic condition of “average vehicle speed at OO intersection” is exemplified as a statistic of a simulation result and the real data to be compared. Also, as a parameter for data assimilation, the values before and after the change of “indication time of green light at OO intersection” are exemplified.

In this way, the simulation device 10 can improve the accuracy of simulation by bringing the simulation result closer to the actual situation. Further, by repeating this processing, it is possible to easily and highly accurately determine an optimum parameter and perform a highly accurate simulation.

### Simulation Processing

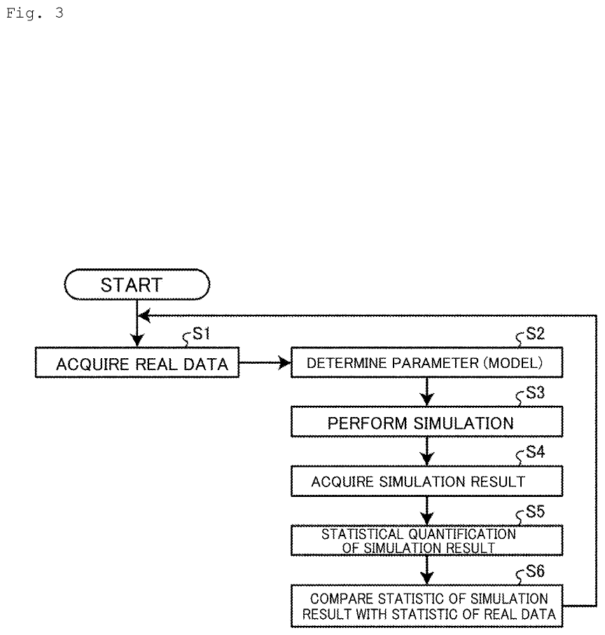

Next, simulation processing by the simulation device 10 according to the present embodiment will be described with reference to FIG. 3. FIG. 3 is a flowchart illustrating a simulation processing procedure. The flowchart of FIG. 3 is started, for example, at the timing at which the user inputs an operation instructing the start.

First, the acquisition unit 15a acquires data such as actual statistical information (step S1). For example, in a case where a simulation related to traffic is performed, the acquisition unit 15a acquires traffic condition data such as position information by GPS, average vehicle speed and number of passing vehicles at a fixed point by a traffic counter or ETC, and camera images.

Next, the calculation unit 15b performs a simulation using a predetermined parameter of the prediction model and calculates a simulation result (steps S2 to S4). Specifically, the calculation unit 15b performs a simulation using a predetermined default value as a parameter in the first iteration of simulation processing.

Then, the selection unit 15c compares the simulation result with the real data corresponding to the simulation result, and selects a parameter such that the simulation result is assimilated with the real data (steps S5 and S6). Then, the selection unit 15c feeds back the selected parameter to the calculation unit 15b, and returns the processing to step S1.

Then, the selection unit 15c repeats the processing of steps S1 to S6 until the simulation result shows accuracy equal to or higher than a predetermined threshold value or until the number of times of simulation reaches a predetermined number of times. Thus, a series of simulation processing ends.

### Other Embodiments

The processing target of the simulation device 10 is not limited to the above embodiment. For example, the calculation unit 15b may perform a simulation related to weather. Only processing different from the above embodiment will be described below.

In this case, the acquisition unit 15a acquires real data, such as data from AMeDAS or a uniquely set weather sensor, cloud cover data obtained from an installed camera image, and the like.

Further, the calculation unit 15b calculates weather data such as temperature, atmospheric pressure, humidity, wind direction, and wind speed for each mesh as a simulation result.

The selection unit 15c calculates a statistic from the simulation result. For example, if correct data to be described later is a wind direction or a wind speed over a wide area, averaging of the wind direction and the wind speed of the mesh included in the target area is calculated as a statistic.

The selection unit 15c compares the data acquired from the weather sensor by the acquisition unit 15a as correct data with the statistic of the simulation result, and evaluates quantitative accuracy using the RMSE or the like.

For example, in a case where the temperature at a certain point is abnormally lower than real data in the simulation result, the selection unit 15c reflects, as parameters, factors such as artificial exhaust heat from an air-conditioner outdoor unit or the reflection of light from a building, which increase the temperature at that point, to bring the data closer to the real data.

By performing iteration while improving the accuracy of the simulation in this manner, it is possible to easily and accurately determine optimum parameters and perform highly accurate simulations in the same manner as in the above embodiment.

### Effects

As described above, in the simulation device 10 according to the present embodiment, the acquisition unit 15a acquires real data. The calculation unit 15b calculates performs a simulation using a predetermined parameter and calculates a simulation result. The selection unit 15c compares the simulation result with the real data corresponding to the simulation result, and selects a parameter such that the simulation result and the real data are assimilated. The calculation unit 15b performs the simulation using the selected parameter as the predetermined parameter.

Thus, in the simulation device 10, the accuracy of large-scale simulation can be easily improved by performing iteration while approaching the actual situation. Therefore, according to the simulation device, it is possible to efficiently determine a parameter optimal for large-scale simulation using a prediction model, and to perform highly accurate simulation.

The selection unit 15c repeats a process of selecting the parameter and outputting the parameter to the calculation unit 15b until the simulation result shows accuracy equal to or higher than a predetermined threshold value. Specifically, the selection unit 15c calculates the accuracy using an RMSE or the like between the simulation result and the real data. Thus, the simulation with high accuracy can be reliably performed.

Further, the selection unit 15c repeats the process of selecting the parameter and outputting the parameter to the calculation unit 15b until a predetermined number of times is reached. Thus, the simulation with higher accuracy can be performed.

The selection unit 15c further presents the simulation result and the real data to be compared. In this case, the selection unit 15c further presents a parameter for assimilating the simulation result and the real data. Thus, since the user can check that the accuracy of the simulation is improved, the simulation with high accuracy can be reliably performed.

### Program

A program in which the processing executed by the simulation device 10 according to the above embodiment is described in a computer-executable language can also be created. As an embodiment, the simulation device 10 can be implemented by installing a simulation program for executing the above simulation processing as packaged software or online software in a desired computer. For example, the information processing device can function as the simulation device 10 by causing the information processing device to execute the above simulation program. The information processing device mentioned here includes a desktop or laptop personal computer. Further, a mobile communication terminal such as a smartphone, a mobile phone, or a personal handyphone system (PHS), or a slate terminal such as a personal digital assistant (PDA), for example, is included in a category of the information processing device. Furthermore, the functions of the simulation device 10 may be implemented in a cloud server.

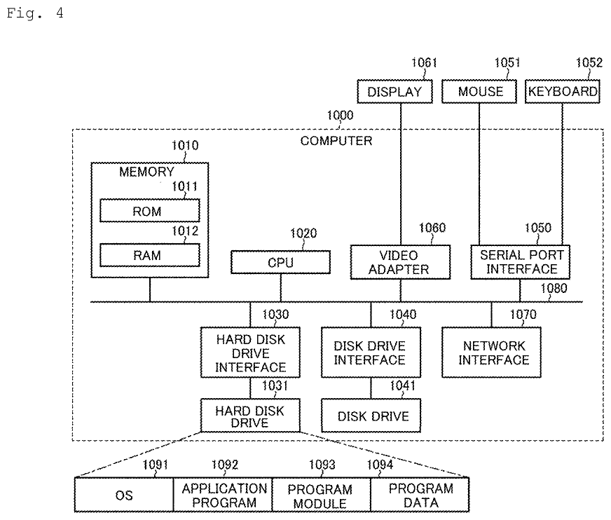

FIG. 4 is a diagram illustrating an example of a computer that executes a simulation program. A computer 1000 includes, for example, a memory 1010, a CPU 1020, a hard disk drive interface 1030, a disk drive interface 1040, a serial port interface 1050, a video adapter 1060, and a network interface 1070. These units are connected by a bus 1080. The memory 1010 includes a read only memory (ROM) 1011 and a RAM 1012. The ROM 1011 stores, for example, a boot program, such as a basic input output system (BIOS). The hard disk drive interface 1030 is connected to a hard disk drive 1031. The disk drive interface 1040 is connected to a disk drive 1041. A detachable storage medium such as a magnetic disk or an optical disc, for example, is inserted into the disk drive 1041. A mouse 1051 and a keyboard 1052, for example, are connected to the serial port interface 1050. A display 1061, for example, is connected to the video adapter 1060.

Here, the hard disk drive 1031 stores, for example, an OS 1091, an application program 1092, a program module 1093, and program data 1094. Each of the pieces of information described in the above embodiment is stored in, for example, the hard disk drive 1031 or the memory 1010.

For example, the simulation program is stored in the hard disk drive 1031 as the program module 1093 in which instructions executed by the computer 1000 are described. Specifically, the program module 1093 in which each piece of processing executed by the simulation device 10 described in the above embodiment is described is stored in the hard disk drive 1031.

Data used for information processing by the simulation program is stored in, for example, the hard disk drive 1031 as the program data 1094. Then, the CPU 1020 reads the program module 1093 and the program data 1094 stored in the hard disk drive 1031 to the RAM 1012 as necessary, and executes each of the above-described procedures.

Note that the program module 1093 and the program data 1094 related to the simulation program are not limited to being stored in the hard disk drive 1031, and may be stored in, for example, a detachable storage medium and read by the CPU 1020 via the disk drive 1041 or the like. Alternatively, the program module 1093 and the program data 1094 related to the simulation program may be stored in another computer connected via a network such as a LAN or a wide area network (WAN) and read by the CPU 1020 via the network interface 1070.

Although the embodiments to which the invention made by the present inventors is applied have been described above, the present invention is not limited by the description and the drawings forming a part of the disclosure of the present invention according to the present embodiments. In other words, other embodiments, examples, operational technologies, and the like made by those skilled in the art and the like on the basis of the present embodiment are all included in the scope of the present invention.

### REFERENCE SIGNS LIST

10 Simulation device
11 Input unit
12 Output unit
13 Communication control unit
14 Storage unit
15 Control unit
15a Acquisition unit
15b Calculation unit
15c Selection unit

1. A simulation system comprising:
at least one processor; and
memory storing instructions that, when executed by the at least one processor, causes the system to perform a set of operations, the set of operations comprising:
acquiring real data;
performing a simulation using a predetermined parameter and calculate a simulation result; and
comparing the simulation result with the real data corresponding to the simulation result, and select a parameter such that the simulation result and the real data are assimilated,
wherein the simulation using the selected parameter as the predetermined parameter.

2. The simulation device according to claim 1, wherein a process of selecting the parameter and outputting the parameter is repeated until the simulation result shows accuracy equal to or higher than a predetermined threshold value.

3. The simulation device according to claim 2, wherein the accuracy using a root mean squared error is calculated between the simulation result and the real data.

4. The simulation device according to claim 1, wherein a process of selecting the parameter and outputting the parameter is repeated until a predetermined number of times is reached.

5. The simulation device according to claim 1, wherein the simulation result is presented and the real data to be compared.

6. The simulation device according to claim 5, wherein a parameter for assimilating the simulation result and the real data is presented.

7. A simulation method executed by a simulation device, the simulation method comprising:
acquiring real data;
performing a simulation using a predetermined parameter and calculating a simulation result; and
comparing the simulation result with the real data corresponding to the simulation result, and selecting a parameter such that the simulation result and the real data are assimilated,
wherein the simulation is performed using the selected parameter as the predetermined parameter.

8. (canceled)

9. A computer-readable non-transitory recording medium storing computer-executable program instructions that when executed by a processor cause a computer to execute a program generation method comprising:
acquiring real data;
performing a simulation using a predetermined parameter and calculate a simulation result; and
comparing the simulation result with the real data corresponding to the simulation result, and select a parameter such that the simulation result and the real data are assimilated,
wherein the simulation using the selected parameter as the predetermined parameter.

10. The simulation device according to claim 1, wherein a plurality of parameter sets is used to execute simulating in parallel.

11. The simulation device according to claim 1, wherein the parameter is updated based on the simulation result.

12. The simulation method according to claim 7, wherein a plurality of parameter sets is used to execute simulating in parallel.

13. The simulation method according to claim 7, wherein the parameter is updated based on the simulation result.
